(19) United States
(12) Patent Application Publication
(10) Pub. No.: US 2014/0138233 A1
(43) Pub. Date: May 22, 2014

(54) LUMINOUS KEYBOARD

(71) Applicant: PRIMAX ELECTRONICS LTD., Taipei (TW)

(72) Inventor: Chung-Yuan Chen, Taipei (TW)

(73) Assignee: PRIMAX ELECTRONICS LTD., Taipei (TW)

(21) Appl. No.: 13/801,423

(22) Filed: Mar. 13, 2013

(30) Foreign Application Priority Data
Nov. 21, 2012 (TW) 101143412

(51) Int. Cl. F21V 8/00; H03K 17/96

(52) U.S. Cl. CPC G02B 6/0055; H03K 17/9622
USPC 200/5 R

(57) ABSTRACT

A luminous keyboard includes a lateral-emitting type illumination element, a light guide plate, a reflective plate, a sensing circuit pattern, and plural keys. The lateral-emitting type illumination element is used for providing a light beam to the light guide plate, so that the light beam is diffused to the whole light guide plate. The light guide plate has plural light-guiding dots for collecting and scattering the light beam. The portion of the light beam scattered upwardly by the light-guiding dots is projected to the plural keys. The portion of the light beam scattered downwardly is reflected by the reflective plate and incident into the light guide plate again. The sensing circuit pattern is formed on a surface of the reflective plate. When any key is moved toward the sensing circuit pattern, the sensing circuit pattern generates a corresponding non-contact key signal.

### FIELD OF THE INVENTION

The present invention relates to a luminous keyboard, and more particularly to a luminous keyboard with an illuminating function.

### BACKGROUND OF THE INVENTION

Recently, with increasing development of information industries, portable information devices such as notebook computers, mobile phones or personal digital assistants are widely used in many instances. In a case that a portable information device is used in a dim environment, the numbers and the characters marked on the keys of the keyboard of the portable information device are not clearly visible. In other words, the dim environment becomes hindrance from operating the keyboard. In addition, if the numbers and the characters marked on the keys of the keyboard are reluctantly viewed in the dim environment, the user is readily suffered from vision impairment. For solving these drawbacks, a luminous keyboard has been disclosed. The luminous keyboard can be used in the dim environment in order to enhance the applications thereof. Moreover, by changing the layout of the luminous regions of the luminous keyboard, the information device having the luminous keyboard is more aesthetically-pleasing and thus the competiveness thereof is enhanced.

FIG. 1 is a schematic cross-sectional view illustrating a conventional luminous keyboard. As shown in FIG. 1, the luminous keyboard 1 comprises a reflector 11, a light guide plate 12, a supporting plate 13, a membrane wiring board 14, plural keys 15, and plural lateral-emitting type illumination elements 16. The membrane wiring board 14 comprises a lower wiring plate 141, an upper wiring plate 142, and an intermediate plate 143. The intermediate plate 143 is arranged between the lower wiring plate 141 and the upper wiring plate 142. The lower wiring plate 141, the intermediate plate 143 and the upper wiring plate 142 are all made of transparent light-guiding material. The transparent light-guiding material includes for example polycarbonate (PC) or polyethylene terephthalate (PET).

Please refer to FIG. 2, which is a schematic exploded view illustrating a membrane wiring board of the conventional luminous keyboard of FIG. 1. The lower wiring plate 141 comprises a first circuit pattern 1411. The first circuit pattern 1411 comprises plural silver paste conductive element lines 14111 and plural lower contacts 14112. The upper wiring plate 142 comprises a second circuit pattern 1421. The second circuit pattern 1421 comprises plural silver paste conductive element lines 14211 and plural upper contacts 14212. The intermediate plate 143 comprises plural perforations 1431 corresponding to the plural lower contacts 14112 and the plural upper contacts 14212, respectively. Each of the upper contacts 14212 and the corresponding lower contact 14112 are collectively defined as a membrane switch 144.

The supporting plate 13 is disposed under the membrane wiring board 14. In addition, the supporting plate 13 comprises plural openings 131, a first fixing structure 132, and a second fixing structure 133. Each of the keys 15 comprises a keycap 151, an elastic element 152, and a scissors-type connecting element 153. The keycap 151 comprises a first keycap connecting structure 1511 and a second keycap connecting structure 1512. The scissors-type connecting element 153 comprises a first frame 1531 and a second frame 1532. In addition, the elastic element 152 is arranged between the keycap 151 and the membrane wiring board 14.

The membrane wiring board 14 further comprises apertures 145 and 146 (see FIG. 1). The first fixing structure 132 and the second fixing structure 133 are penetrated through the apertures 145 and 146, respectively. A first end 15311 of the first frame 1531 is connected to the second fixing structure 133, and a second end 15312 of the first frame 1531 is connected to the first keycap connecting structure 1511. In addition, a first end 15321 of the second frame 1532 is connected to the first fixing structure 132, and a second end 15322 of the second frame 1532 is connected to the second keycap connecting structure 1512.

As any key 15 is depressed and moved downwardly relative to the supporting plate 13, the first frame 1531 and the second frame 1532 of the scissors-type connecting element 153 are switched from an open-scissors state to a folded state. Moreover, as the keycap 151 is moved downwardly to compress the elastic element 152, the corresponding upper contact 14212 is pushed by the elastic element 152. Consequently, the upper contact 14212 is penetrated through the corresponding perforation 1431 to be contacted with the corresponding lower contact 14112. Consequently, the corresponding membrane switch 144 is electrically conducted, and the luminous keyboard 1 generates the corresponding key signal. When the depressing force exerted on the key 15 is eliminated, an elastic force provided by the elastic element 152 is acted on the keycap 151. In response to the elastic force, the keycap 151 is moved upwardly relative to the supporting plate 13. Meanwhile, the first frame 1531 and the second frame 1532 of the scissors-type connecting element 153 are switched from the folded state to the open-scissors state, and the keycap 151 is returned to its original position.

Moreover, the lateral-emitting type illumination elements 16 are located at bilateral sides of the light guide plate 12 for emitting light beams. The light beams are incident into the light guide plate 12. The light guide plate 12 is disposed on the reflector 11. Plural light-guiding dots 121 are formed on a bottom surface of the light guide plate 12 for collecting and scattering the light beams. The light-guiding dots 121 are aligned with corresponding keys 15. After the light beams are incident into the light guide plate 12, the light beams are diffused into the whole light guide plate 12. Due to the ink properties of the light-guiding dots 121, the light beams will be scattered upwardly and downwardly. The portions of the light beams that are scattered upwardly will be sequentially transmitted through the openings 131 of the supporting plate 13 and the membrane wiring board 14 and then projected to the plural keys 15. The portions of the light beams that are scattered downwardly will be reflected by the reflector 11, and the reflected light beams are directed upwardly. Consequently, the light beams provided by the illumination elements 16 can be well utilized to illuminate the plural keys 15. However, the conventional luminous keyboard 1 still has the following drawbacks.

Firstly, although the reflector 11 can facilitate the light beams which are scattered downwardly from the light-guiding dots 121 to be reflected upwardly, the arrangement of the reflector 11 may increase the overall thickness of the luminous keyboard 1. In other words, the conventional luminous keyboard 1 fails to meet the requirements of light weightiness, slimness and miniaturization.

Secondly, since the travelling distance of the scissors-type connecting element 153 is long, the luminous keyboard 1 should have sufficient space to allow normal operations of the scissors-type connecting element 153. The necessary space is detrimental to the reduction of the thickness of the luminous keyboard 1. In other words, the conventional luminous keyboard 1 fails to meet the requirements of light weightiness, slimness and miniaturization.

Recently, a capacitive sensing keyboard is disclosed. As the keycap is depressed, the electric field of a corresponding capacitive switch of a circuit board of the capacitive sensing keyboard is changed. In response to the change of the electric field, the circuit board generates a corresponding key signal. Since the scissors-type connecting element is not an essential component of the capacitive sensing keyboard, if the scissors-type connecting element is not used, the overall thickness of the capacitive sensing keyboard is effectively reduced. However, since the current capacitive sensing keyboard has no illuminating function, if the capacitive sensing keyboard is used in the dim environment, some problems occur. For example, since the numbers and the characters marked on the keys of the capacitive sensing keyboard are not clearly visible, the dim environment becomes hindrance from operating the capacitive sensing keyboard or the user is readily suffered from vision impairment.

### SUMMARY OF THE INVENTION

The present invention relates to a luminous keyboard, and more particularly to a non-contact sensing luminous keyboard.

In accordance with an aspect of the present invention, there is provided a luminous keyboard. The luminous keyboard includes a luminous keyboard. The luminous keyboard includes at least one lateral-emitting type illumination element, a light guide plate, a reflective plate, a sensing circuit pattern, and at least one key. The at least one lateral-emitting type illumination element is used for providing a light beam. The light guide plate has plural light-guiding dots for collecting and scattering the light beam from the at least one lateral-emitting type illumination element. The at least one lateral-emitting type illumination element is located at a side of the light guide plate. The reflective plate is disposed under the light guide plate for reflecting the light beam from the light guide plate. The sensing circuit pattern is used for generating at least one non-contact key signal. The at least one key is disposed over the light guide plate. When the at least one key is depressed, the at least one non-contact key signal is correspondingly generated by the sensing circuit pattern. The sensing circuit pattern is formed on a surface of the reflective plate.

In an embodiment, the at least one key includes a keycap and a conductive element. The keycap is exposed outside the luminous keyboard. The conductive element is arranged between the keycap and the sensing circuit pattern, and movable with the keycap. As the keycap is depressed, the conductive element is moved downwardly toward the sensing circuit pattern, so that the at least one non-contact key signal is correspondingly generated by the sensing circuit pattern.

In an embodiment, the conductive element is made of conductive foam, metallic material or metallic paint.

In an embodiment, the luminous keyboard further includes a supporting plate. The supporting plate is arranged between the light guide plate and the at least one key for supporting and connecting the at least one key.

In an embodiment, the supporting plate is a light-transmissible supporting plate.

In an embodiment, the supporting plate includes at least one opening corresponding to the at least one key.

In an embodiment, the at least one key further includes a connecting element. The connecting element is connected between the supporting plate and the keycap, so that the keycap is movable upwardly or downwardly relative to the supporting plate.

In an embodiment, the connecting element is a scissors-type connecting element.

In an embodiment, the at least one key further includes an elastic element. The elastic element is arranged between the supporting plate and the keycap. When a depressing force exerted on the keycap is eliminated, the elastic element provides an elastic force. In response to the elastic force, the keycap is returned to an original position.

In an embodiment, the at least one key further includes a key frame and plural elastic arms. The key frame is disposed on the supporting plate, and includes a hollow portion. The keycap is embedded into the hollow portion of the key frame. The plural elastic arms are used for allowing the keycap to be moved upwardly or downwardly relative to the reflective plate. Each of the plural elastic arms includes a static inner arm part, a movable outer arm part and an angular transition part. The angular transition part is connected between the static inner arm part and the movable outer arm part.

In an embodiment, the at least one key further includes plural elastic arms for allowing the keycap to be moved upwardly or downwardly relative to the reflective plate. Moreover, each elastic arm includes a fixed end connected with the supporting plate and a free end connected with the keycap.

In an embodiment, the sensing circuit pattern includes at least one first electrode pattern and at least one second electrode pattern. When the sensing circuit pattern is electrically conducted, an electric field between the at least one first electrode pattern and the at least one second electrode pattern is generated. As the at least one key is depressed and moved toward the sensing circuit pattern, the electric field is changed, so that the at least one non-contact key signal is correspondingly generated by the sensing circuit pattern.

In an embodiment, the luminous keyboard further includes a metal base plate, wherein the metal base plate is disposed under the sensing circuit pattern.

In an embodiment, the at least one lateral-emitting type illumination element is a light emitting diode.

In an embodiment, the luminous keyboard is a capacitive sensing luminous keyboard.

In an embodiment, the light guide plate is made of polyethylene terephthalate (PET), polycarbonate (PC), thermoplastic polyurethane (TPU) or polymethylmethacrylate (PMMA).

In an embodiment, the sensing circuit pattern is formed on a top surface of the reflective plate, or the sensing circuit pattern is formed on a bottom surface of the reflective plate.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating a conventional luminous keyboard;

FIG. 2 is a schematic exploded view illustrating a membrane wiring board of the conventional luminous keyboard of FIG. 1;

FIG. 3 is a schematic cross-sectional view illustrating a luminous keyboard according to a first embodiment of the present invention;

FIG. 4 is a schematic perspective view illustrating a sensing circuit pattern formed on a bottom surface of reflective plate of the luminous keyboard of FIG. 3;

FIG. 5 is a schematic top view illustrating a keycap of the luminous keyboard of FIG. 3;

FIG. 6 is a schematic cross-sectional view illustrating a luminous keyboard according to a second embodiment of the present invention;

FIG. 7 is a schematic cross-sectional view illustrating a luminous keyboard according to a third embodiment of the present invention;

FIG. 8 is a schematic cross-sectional view illustrating a luminous keyboard according to a fourth embodiment of the present invention;

FIG. 9 is a schematic exploded view illustrating a key of the luminous keyboard of FIG. 8;

FIG. 10 is a schematic cutaway view illustrating the key of the luminous keyboard of FIG. 8, in which the key is not depressed;

FIG. 11 is a schematic cutaway view illustrating the key of the luminous keyboard of FIG. 8, in which the key is depressed;

FIG. 12 is a schematic cross-sectional view illustrating a luminous keyboard according to a fifth embodiment of the present invention;

FIG. 13 is a schematic exploded view illustrating a key and a light-transmissible supporting plate of a luminous keyboard according to a sixth embodiment of the present invention;

FIG. 14 is a schematic cross-sectional view illustrating a luminous keyboard according to a seventh embodiment of the present invention; and

FIG. 15 is a schematic cross-sectional view illustrating a luminous keyboard according to an eighth embodiment of the present invention.

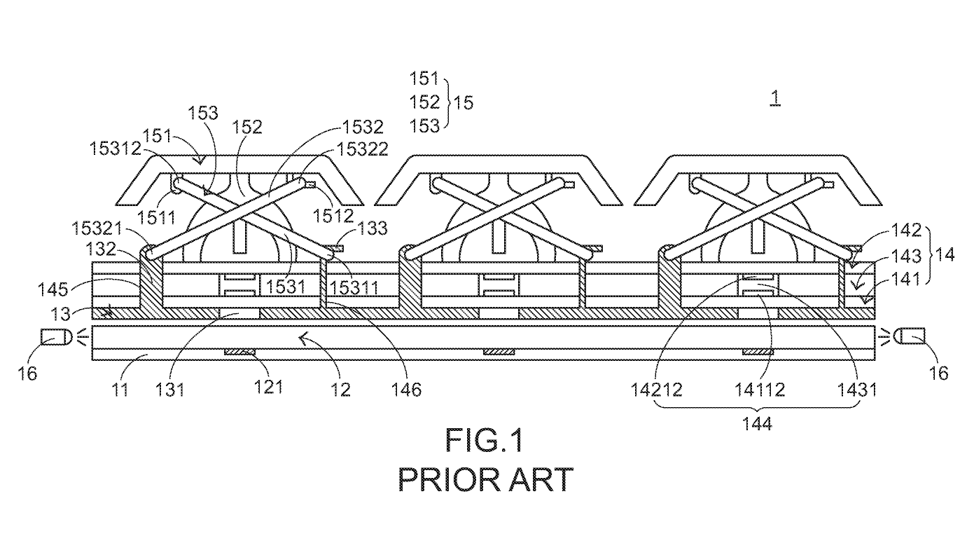

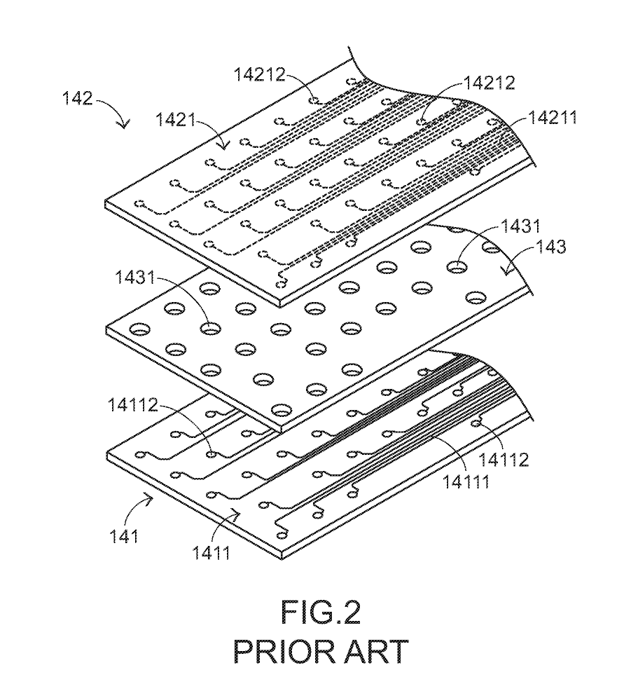

### DETAILED DESCRIPTION OF THE PREFERRED EMBODIMENT

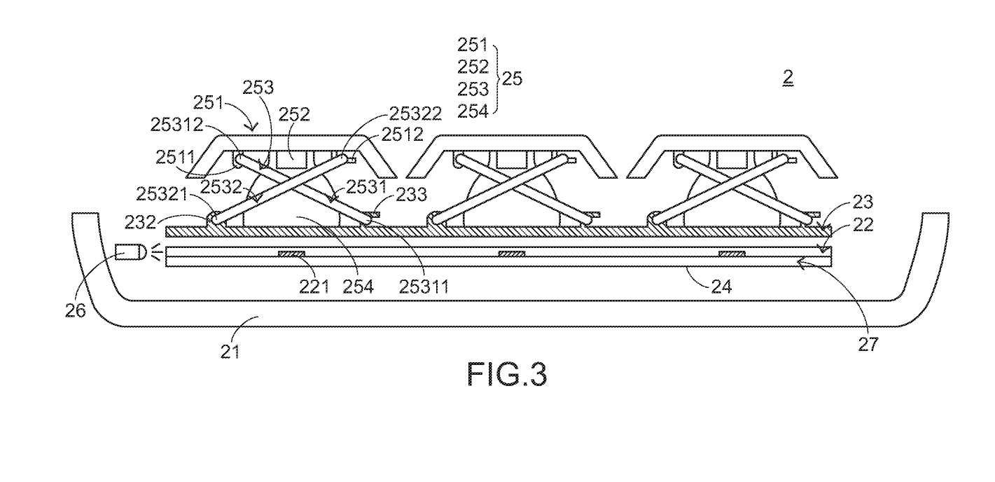

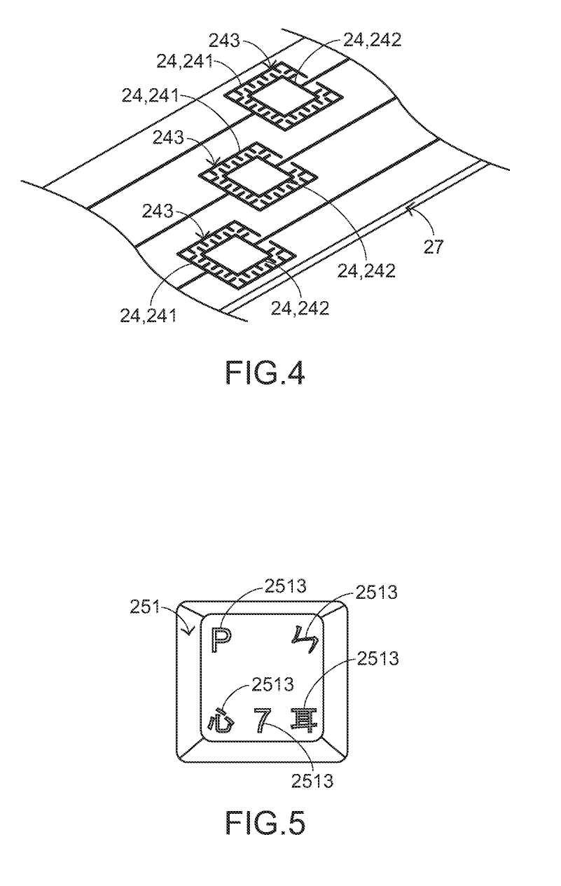

FIG. 3 is a schematic cross-sectional view illustrating a luminous keyboard according to a first embodiment of the present invention. FIG. 4 is a schematic perspective view illustrating a sensing circuit pattern formed on a bottom surface of reflective plate of the luminous keyboard of FIG. 3. FIG. 5 is a schematic top view illustrating a keycap of the luminous keyboard of FIG. 3. Please refer to FIGS. 3, 4 and 5.

From bottom to top, a base 21, a sensing circuit pattern 24, a reflective plate 27, a light guide plate 22, a supporting plate 23 and plural keys 25 are sequentially shown. The luminous keyboard 2 further comprises a lateral-emitting type illumination element 26. The lateral-emitting type illumination element 26 is located at a lateral side of the light guide plate 22. The base 21 is used for supporting the sensing circuit pattern 24, the reflective plate 27, the light guide plate 22, the supporting plate 23, the plural keys 25 and the lateral-emitting type illumination element 26. In addition, the sensing circuit pattern 24 is formed on a bottom surface of the reflective plate 27.

The supporting plate 23 is used for supporting and connecting the plural keys 25. Each key 25 comprises a keycap 251, a conductive element 252, and a connecting element 253. Each connecting element 253 is arranged between the supporting plate 23 and the corresponding keycap 251 for connecting the supporting plate 23 and the corresponding keycap 251. Moreover, due to the connecting element 253, the keycap 251 is movable upwardly or downwardly relative to the supporting plate 23. Each conductive element 252 is connected to a bottom surface of the corresponding keycap 251, and movable relative to the corresponding keycap 251. The conductive element 252 is made of conductive material. An example of the conductive material includes but is not limited to conductive foam, metallic material, graphite or metallic paint. Moreover, the keycap 251 comprises at least one light-outputting 2513. For example, the light-outputting region 2513 is a light-outputting symbol region, a light-outputting number region or a light-outputting character region.

Moreover, in this embodiment, the lateral-emitting type illumination element 26 is a light-emitting diode. The light guide plate 22 is made of polyethylene terephthalate (PET), polycarbonate (PC), thermoplastic polyurethane (TPU) or polymethylmethacrylate (PMMA), but is not limited thereto. The lateral-emitting type illumination element 26 is used for emitting a light beam. The light beam is incident into the light guide plate 22. Moreover, plural light-guiding dots 221 are formed on a surface of the light guide plate 22 for collecting and scattering the light beam. The light-guiding dots 221 are aligned with corresponding keys 25, respectively. After the light beam is incident into the light guide plate 22, the light beam is diffused into the whole light guide plate 22. Due to the properties (e.g. the ink properties) or the structures (e.g. microstructures) of the plural light-guiding dots 221, the light beam will be scattered upwardly and downwardly. In this embodiment, the supporting plate 23 is a light-transmissible supporting plate. The portion of the light beam that is scattered upwardly by the plural light-guiding dots 221 will be sequentially transmitted through the supporting plate 23 and projected to the plural keys 25, and then outputted from the light-outputting region 2513 of the keycap 251. Under this circumstance, the illuminated symbol, number or character of the key 25 is clearly visible to the user, and thus the operating difficulty in the dim environment can be overcome.

Moreover, the portion of the light beam that is scattered downwardly will be reflected by the reflective plate 27, and the reflected light beam is incident into the light guide plate 22 again. Since the portion of the light beam that is provided by the lateral-emitting type illumination element 26 and scattered downwardly is not lost, the light beam provided by the illumination elements 26 can be well utilized. Consequently, the light utilization efficiency of the luminous keyboard 2 is enhanced.

In this embodiment, the luminous keyboard 2 is a capacitive luminous keyboard, and the sensing circuit pattern 24 is a capacitive sensing circuit pattern. The sensing circuit pattern 24 comprises plural first electrode patterns 241 and plural second electrode patterns 242 corresponding to the plural first electrode patterns 241, respectively. Each of the plural first electrode patterns 241 and the corresponding second electrode patterns 242 are separated from each other by a gap. Moreover, each of the plural first electrode patterns 241 and the corresponding second electrode patterns 242 are collaboratively defined as a capacitive key switch 243. When the sensing circuit pattern 24 is electrically conducted, plural electric fields are generated between the first electrode patterns 241 and the corresponding second electrode patterns 242. If one of the electric fields is changed, the corresponding capacitive key switch 243 is triggered, so that the sensing circuit pattern 24 generates a non-contact key signal.

In this embodiment, each first electrode pattern 241 and the corresponding second electrode patterns 242 are discretely arranged on the same horizontal plane. It is noted that numerous modifications and alterations may be made while retaining the teachings of the invention. For example, in some other embodiments, each first electrode pattern 241 and the corresponding second electrode pattern 242 may be discretely arranged on different horizontal planes. That is, each first electrode pattern 241 may be disposed over or under the corresponding second electrode patterns 242. Moreover, a spacer layer (e.g. an UV adhesive layer) is coated or printed on the region between each first electrode pattern 241 and the corresponding second electrode pattern 242. Consequently, each first electrode pattern 241 and the corresponding second electrode pattern 242 are separated from each other vertically.

The way of generating the key signal in the capacitive sensing manner and the operating principle thereof are well known to those skilled in the art, and are not redundantly described herein. The configuration of the sensing circuit pattern 24 of FIG. 4 is presented herein for purpose of illustration and description only. It is noted that numerous modifications and alterations of the sensing circuit pattern 24 may be made while retaining the teachings of the invention. For example, in some other embodiments, the sensing circuit pattern 24 is a magnetic sensing circuit pattern or any other comparable non-contact sensing circuit pattern.

In this embodiment, the connecting element 253 of each key 25 is a scissors-type connecting element. Moreover, the scissors-type connecting element 253 comprises a first frame 2531 and a second frame 2532. The supporting plate 23 further comprises a first fixing structure 232 and a second fixing structure 233. The keycap 251 of each key 25 comprises a first keycap connecting structure 2511 and a second keycap connecting structure 2512. A first end 25311 of the first frame 2531 is connected to the second fixing structure 233, and a second end 25312 of the first frame 2531 is connected to the first keycap connecting structure 2511. In addition, a first end 25321 of the second frame 2532 is connected to the first fixing structure 232, and a second end 25322 of the second frame 2532 is connected to the second keycap connecting structure 2512. It is noted that the connection relationships between the connecting element 253, the supporting plate 23 and the keycap 251 are presented herein for purpose of illustration and description only.

The plural keys 25 are aligned with the plural capacitive key switches 243, respectively. As any keycap 251 is depressed and moved downwardly relative to the supporting plate 23, the first frame 2531 and the second frame 2532 of the corresponding connecting element 253 are switched from an open-scissors state to a folded state. Moreover, as the keycap 251 is moved downwardly, the corresponding conductive element 252 is moved toward the sensing circuit pattern 24. Under this circumstance, the electric field between the corresponding first electrode pattern 241 and the corresponding second electrode pattern 242 is changed. Due to the change of the electric field, the corresponding capacitive key switch 243 is triggered. Consequently, the sensing circuit pattern 24 generates the corresponding non-contact key signal.

Moreover, each key 25 further comprises an elastic element 254. The elastic element 254 is arranged between the keycap 251 and the supporting plate 23. When the depressing force exerted on the keycap 251 is eliminated, an elastic force provided by the corresponding elastic element 254 is acted on the keycap 251. In response to the elastic force, the keycap 251 is moved upwardly relative to the supporting plate 23. Under this circumstance, the first frame 2531 and the second frame 2532 are switched from the folded state to the open-scissors state, and the keycap 251 is returned to its original position. Moreover, the elastic element 254 also provides a feedback tactile feel of depressing the keycap 251 to the user. The way of returning the keycap 251 to its original position by the elastic element 254 is presented herein for purpose of illustration and description only. However, those skilled in the art will readily observe that numerous modifications and alterations may be made according to the practical requirements.

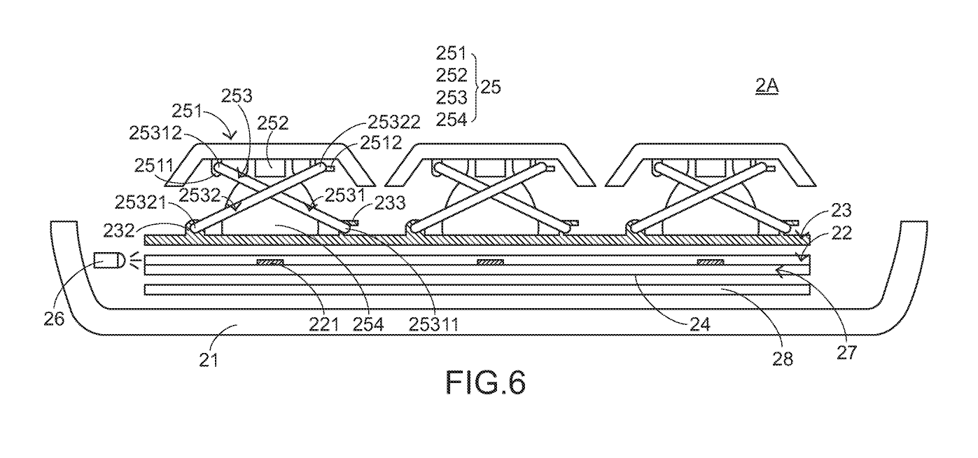

FIG. 6 is a schematic cross-sectional view illustrating a luminous keyboard according to a second embodiment of the present invention. Except that the luminous keyboard 2A of this embodiment further comprises a metal base plate 28, the other components of the luminous keyboard 2A are similar to those of the luminous keyboard of the first embodiment, and are not redundantly described herein. The metal base plate 28 is disposed under the sensing circuit pattern 24 for providing a shielding effect. Due to the shielding effect, the interference between the electric fields of every two adjacent capacitive key switches 243 can be inhibited.

Those skilled in the art will readily observe that the metal base plate 28 of the luminous keyboard of the second embodiment may be applied to the luminous keyboards of the following embodiments while retaining the teachings of the second embodiment of the present invention.

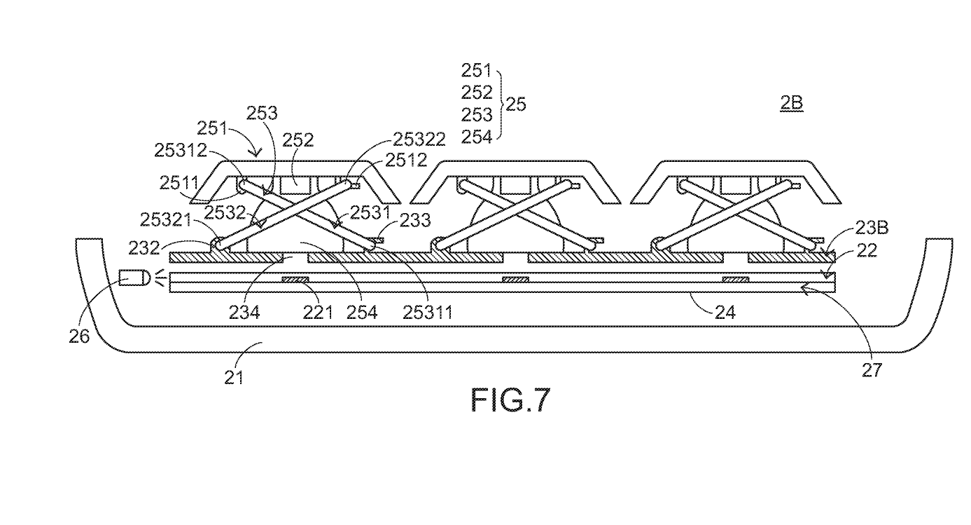

FIG. 7 is a schematic cross-sectional view illustrating a luminous keyboard according to a third embodiment of the present invention. Except that the following items, the other components of the luminous keyboard 2B of this embodiment are similar to those of the luminous keyboard of the first embodiment, and are not redundantly described herein. In comparison with the first embodiment, the supporting plate 23B of the luminous keyboard 2B of this embodiment is not a light-transmissible supporting plate. Moreover, the supporting plate 23B comprises plural openings 234 corresponding to the plural keys 25, respectively. Consequently, the portion of the light beam that is scattered upwardly by the plural light-guiding dots 221 can be transmitted through the corresponding openings 234 and then projected to the corresponding keycaps 251.

In the above embodiments, the cooperation of the supporting plate 23 or 23B and the scissors-type connecting element 253 allows the keycap 251 and the conductive element 252 to be moved upwardly or downwardly relative to the sensing circuit pattern 24. The way of allowing the keycap 251 and the conductive element 252 to be moved upwardly or downwardly relative to the sensing circuit pattern 24 is presented herein for purpose of illustration and description only. However, those skilled in the art will readily observe that numerous modifications and alterations may be made according to the practical requirements. It is noted that the scissors-type connecting element 253 is not an essential component for limiting the scopes of the present invention.

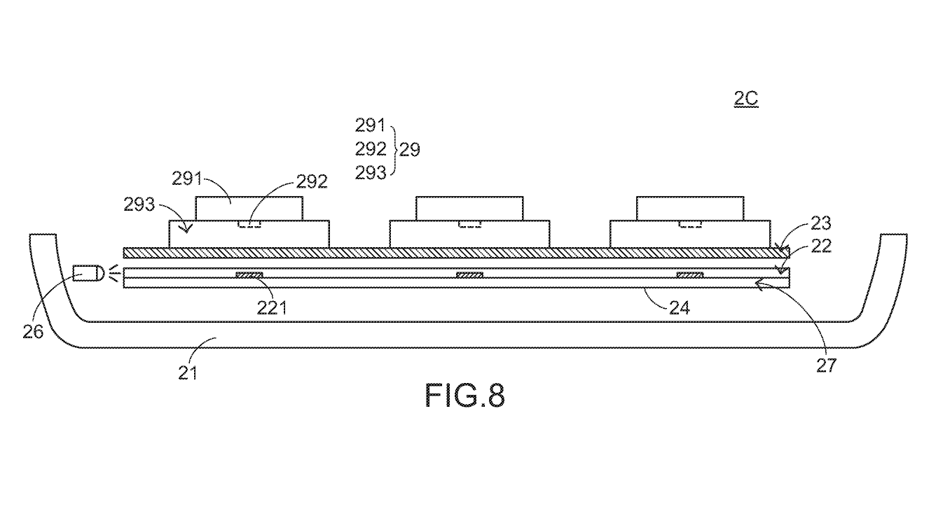

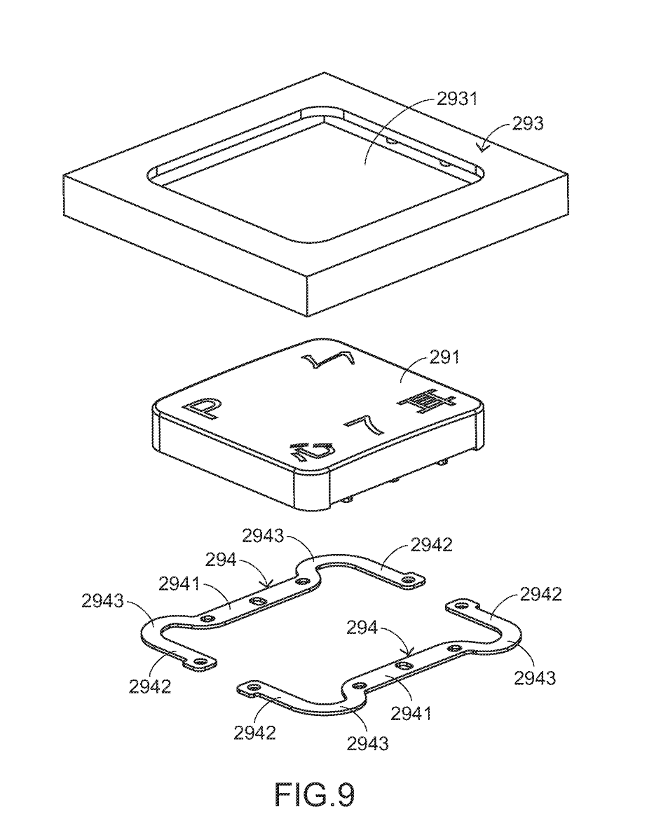

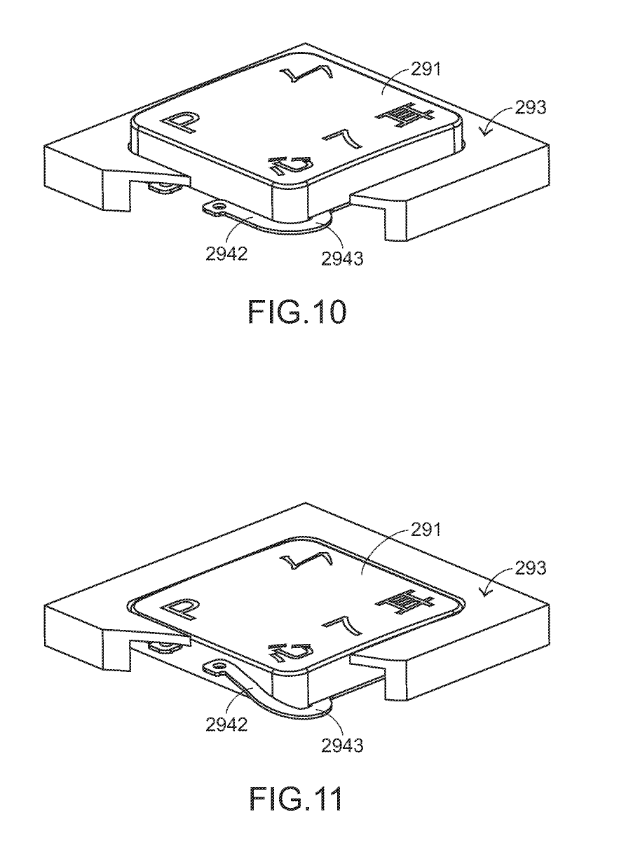

Hereinafter, another embodiment of a luminous keyboard will be illustrated with reference to FIGS. 8-11. FIG. 8 is a schematic cross-sectional view illustrating a luminous keyboard according to a fourth embodiment of the present invention. FIG. 9 is a schematic exploded view illustrating a key of the luminous keyboard of FIG. 8. FIG. 10 is a schematic cutaway view illustrating the key of the luminous keyboard of FIG. 8, in which the key is not depressed. FIG. 11 is a schematic cutaway view illustrating the key of the luminous keyboard of FIG. 8, in which the key is depressed. Except for the following items, the other components of the luminous keyboard 2C of this embodiment are similar to those of the luminous keyboard of the first embodiment, and are not redundantly described herein.

In comparison with the first embodiment, the scissors-type connecting element 253 is not included in the luminous keyboard 2C of this embodiment. Especially, each key 29 comprises a keycap 291, a conductive element 292, a key frame 293, and plural elastic arms 294. Each of the elastic arms 294 is a flat strip comprising a static inner arm part 2941, a movable outer arm part 2942, and an angular transition part 2943. The movable outer arm part 2942 is perpendicular to the static inner arm part 2941. The angular transition part 2943 is connected between the static inner arm part 2941 and the movable outer arm part 2942. The key frame 293 has a hollow portion 2931. The keycap 291 is embedded into the hollow portion 2931 of the key frame 293. The static inner arm part 2941 of each elastic arm 294 is fixed on the bottom of the keycap 291. The movable outer arm part 2942 of each elastic arm 294 is exposed externally from the bottom of the keycap 291 and fixed on the key frame 293. The angular transition part 2943 of each elastic arm 294 is exposed externally from a corner of the bottom of the keycap 291.

In a case that any keycap 291 is not depressed, the movable outer arm part 2942 and the angular transition part 2943 of each elastic arm 294 are not subjected to deformation (see FIG. 10). As any keycap 291 is depressed, the angular transition part 2943 of the elastic arm 294 is pressed by the corner of the bottom of the keycap 291. Under this circumstance, both of the movable outer arm part 2942 and the angular transition part 2943 of the elastic arm 294 are subjected to deformation (see FIG. 11). Moreover, as the keycap 291 is moved downwardly, the conductive element 292 is correspondingly moved toward the sensing circuit pattern 24. Meanwhile, the corresponding capacitive key switch is triggered, and thus the sensing circuit pattern 24 generates the corresponding non-contact key signal. For clarification and brevity, the capacitive key switch is not shown. The operations of the capacitive key switch are similar to those of the first embodiment, and are not redundantly described herein. When the depressing force exerted on the keycap 291 is eliminated, an elastic force provided by the corresponding elastic arm 294 is acted on the keycap 291. In response to the elastic force, the keycap 291 is returned to its original position.

In the luminous keyboard 2C of this embodiment, the scissors-type connecting element is not included, but the keycap and the conductive element are movable upwardly or downwardly relative to the sensing circuit pattern. Under this circumstance, the overall thickness of the luminous keyboard can be further reduced. The luminous keyboard is presented herein for purpose of illustration and description only. However, those skilled in the art will readily observe that the key structure of the fourth embodiment may be applied to the above embodiments from the first embodiment to the third embodiment while retaining the teachings of the fourth embodiment of the present invention.

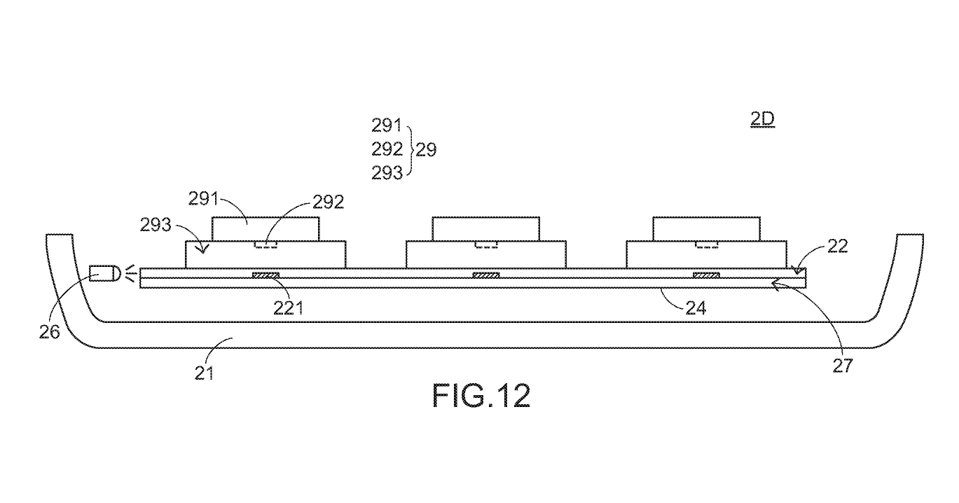

Moreover, the supporting plate 23 is not an essential component for limiting the scopes of the present invention. FIG. 12 is a schematic cross-sectional view illustrating a luminous keyboard according to a fifth embodiment of the present invention. Except that the supporting plate 23 is not included in the luminous keyboard 2D of this embodiment, the other components of the luminous keyboard 2D are similar to those of the luminous keyboard 2C of the fourth embodiment, and are not redundantly described herein. Moreover, in this embodiment, each key 29 is disposed on the light guide plate 22.

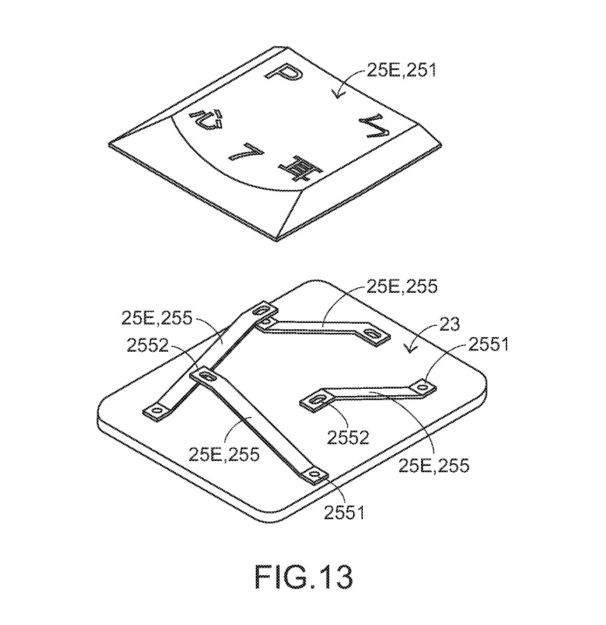

FIG. 13 is a schematic exploded view illustrating a key and a light-transmissible supporting plate of a luminous keyboard according to a sixth embodiment of the present invention. Except for the following items, the other components of the luminous keyboard of this embodiment are similar to those of the luminous keyboard of the first embodiment, and are not redundantly described herein.

In comparison with the first embodiment, the scissors-type connecting element 253 is not included in the luminous keyboard of the sixth embodiment. Moreover, each key 25E further comprises plural elastic arms 255. The plural elastic arms 255 are arranged between the keycap 251 and the supporting plate 23. Each elastic arm 255 comprises a fixed end 2551 and a free end 2552. The fixed end 2551 of each elastic arm 255 is connected with the supporting plate 23. The free end 2552 of each elastic arm 255 is connected with the bottom of the keycap 251. As any keycap 251 is depressed, the free end 2552 of each elastic arm 255 is pressed by the keycap 251. Under this circumstance, the free end 2552 of each elastic arm 255 is moved downwardly with the keycap 251, and the free end 2552 of each elastic arm 255 provides an elastic force to the keycap 251. When the depressing force exerted on the keycap 251 is eliminated, the keycap 251 is returned to its original position in response to the elastic force provided by each elastic arm 255.

However, those skilled in the art will readily observe that the key structure and the relationship between components of the sixth embodiment may be applied to the first, second, third and fifth embodiments while retaining the teachings of the sixth embodiment of the present invention.

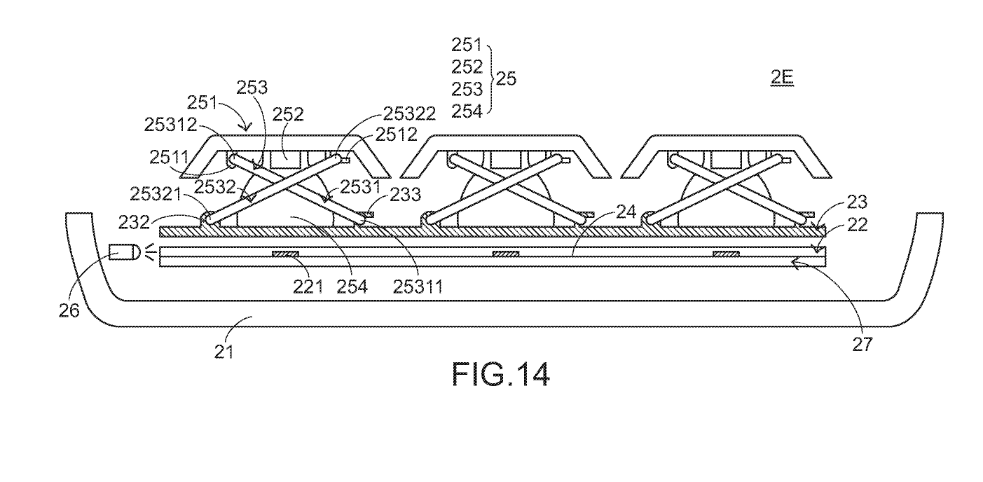

FIG. 14 is a schematic cross-sectional view illustrating a luminous keyboard according to a seventh embodiment of the present invention. Except that the sensing circuit pattern 24 is formed on a top surface of the reflective plate 27 of the luminous keyboard 2E of this embodiment, the other components of the luminous keyboard 2E are similar to those of the luminous keyboard of the first embodiment, and are not redundantly described herein.

However, those skilled in the art will readily observe that the relationship between the sensing circuit pattern 24 and the reflective plate 27 of the seventh embodiment may be applied to the above embodiments while retaining the teachings of the seventh embodiment of the present invention.

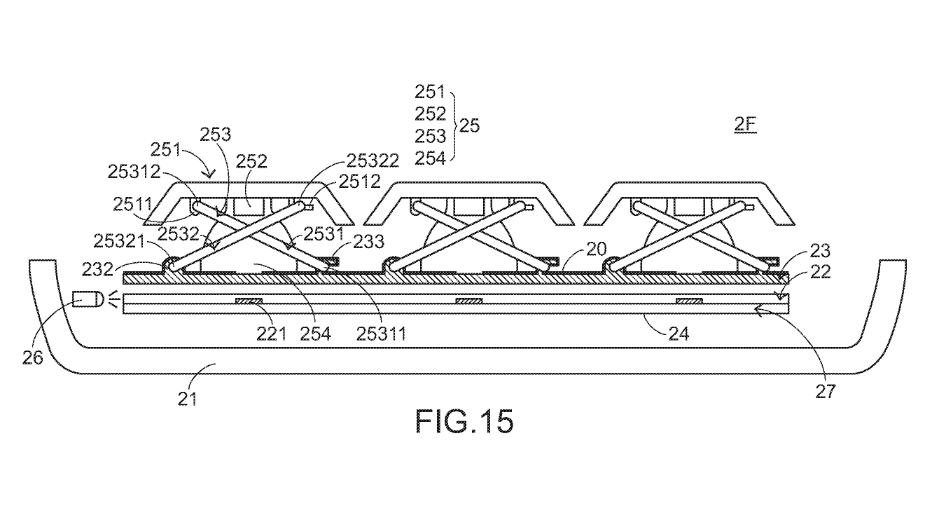

FIG. 15 is a schematic cross-sectional view illustrating a luminous keyboard according to an eighth embodiment of the present invention. Except for the following items, the other components of the luminous keyboard 2F of this embodiment are similar to those of the luminous keyboard of the first embodiment, and are not redundantly described herein. In comparison with the first embodiment, a light-shading structure 20 (e.g. a light-shading layer) is formed on an outer surface of the supporting plate 23. Consequently, the portion of the light beam scattered upwardly by the light-guiding dot 221 fails to be transmitted through the light-shading structure 20, but the light beam is only transmissible through the portion of the supporting plate 23 which is not shaded by the light-shading structure 20. Due to the light-shading structure 20, the light beam fails to be leaked to any place where the light beam is not needed. In this embodiment, the light-shading structure 20 is formed on the outer surface of the supporting plate 23. The luminous keyboard is presented herein for purpose of illustration and description only. It is noted that numerous modifications and alterations may be made while retaining the teachings of the invention. For example, in some other embodiments, the light-shading structure may be formed on an inner surface of the supporting plate 23. Alternatively, the light-shading structure may be formed on the surface of the light guide plate 22.

However, those skilled in the art will readily observe that the light-shading structure 20 of the eighth embodiment may be applied to all of the above embodiments while retaining the teachings of the seventh embodiment of the present invention. That is, in all of the above embodiments, the light-shading structure 20 may be formed on the surface of the supporting plate or the surface of the light guide plate in order to prevent the light beam from being leaked to any place where the light beam is not needed.

From the above descriptions, the present invention provides a luminous keyboard. In the luminous keyboard of the present invention, the sensing circuit pattern is directly formed on a surface of a reflective layer. That is, it is not necessary to provide an additional substrate (e.g. a sensing circuit board) to form the sensing circuit pattern thereon. Consequently, the overall thickness of the luminous keyboard is reduced. Moreover, since the luminous keyboard of the present invention comprises the non-contact sensing circuit pattern, the luminous keyboard of the present invention has industrial applicability when compared with the conventional non-sensing keyboard without the illuminating function.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A luminous keyboard, comprising:
at least one lateral-emitting type illumination element for providing a light beam;
a light guide plate with plural light-guiding dots for collecting and scattering said light beam from said at least one lateral-emitting type illumination element, wherein said at least one lateral-emitting type illumination element is located at a side of said light guide plate;
a reflective plate disposed under said light guide plate for reflecting said light beam from said light guide plate;
a sensing circuit pattern for generating at least one non-contact key signal; and
at least one key disposed over said light guide plate, wherein when said at least one key is depressed, said at least one non-contact key signal is correspondingly generated by said sensing circuit pattern;
wherein said sensing circuit pattern is formed on a surface of said reflective plate.

2. The luminous keyboard according to claim 1, wherein said at least one key comprises:
a keycap exposed outside said luminous keyboard; and
a conductive element arranged between said keycap and said sensing circuit pattern, and movable with said keycap, wherein as said keycap is depressed, said conductive element is moved downwardly toward said sensing circuit pattern, so that said at least one non-contact key signal is correspondingly generated by said sensing circuit pattern.

3. The luminous keyboard according to claim 2, wherein said conductive element is made of conductive foam, metallic material or metallic paint.

4. The luminous keyboard according to claim 2, wherein said luminous keyboard further comprises a supporting plate, wherein said supporting plate is arranged between said light guide plate and said at least one key for supporting and connecting said at least one key.

5. The luminous keyboard according to claim 4, wherein said supporting plate is a light-transmissible supporting plate.

6. The luminous keyboard according to claim 4, wherein said supporting plate comprises at least one opening corresponding to said at least one key.

7. The luminous keyboard according to claim 4, wherein said at least one key further comprises a connecting element, wherein said connecting element is connected between said supporting plate and said keycap, so that said keycap is movable upwardly or downwardly relative to said supporting plate.

8. The luminous keyboard according to claim 7, wherein said connecting element is a scissors-type connecting element.

9. The luminous keyboard according to claim 7, wherein said at least one key further comprises an elastic element, wherein said elastic element is arranged between said supporting plate and said keycap, wherein when a depressing force exerted on said keycap is eliminated, said elastic element provides an elastic force, wherein in response to said elastic force, said keycap is returned to an original position.

10. The luminous keyboard according to claim 4, wherein said at least one key further comprises:
a key frame disposed on said supporting plate, and comprising a hollow portion, wherein said keycap is embedded into said hollow portion of said key frame; and
plural elastic arms for allowing said keycap to be moved upwardly or downwardly relative to said reflective plate, wherein each of said plural elastic arms comprises a static inner arm part, a movable outer arm part and an angular transition part, wherein said angular transition part is connected between said static inner arm part and said movable outer arm part.

11. The luminous keyboard according to claim 4, wherein said at least one key further comprises plural elastic arms for allowing said keycap to be moved upwardly or downwardly relative to said reflective plate, wherein each elastic arm comprises a fixed end connected with said supporting plate and a free end connected with said keycap.

12. The luminous keyboard according to claim 1, wherein said sensing circuit pattern comprises at least one first electrode pattern and at least one second electrode pattern, wherein when said sensing circuit pattern is electrically conducted, an electric field between said at least one first electrode pattern and said at least one second electrode pattern is generated, wherein as said at least one key is depressed and moved toward said sensing circuit pattern, said electric field is changed, so that said at least one non-contact key signal is correspondingly generated by said sensing circuit pattern.

13. The luminous keyboard according to claim 1, wherein said luminous keyboard further comprises a metal base plate, wherein said metal base plate is disposed under said sensing circuit pattern.

14. The luminous keyboard according to claim 1, wherein said at least one lateral-emitting type illumination element is a light emitting diode.

15. The luminous keyboard according to claim 1, wherein said luminous keyboard is a capacitive sensing luminous keyboard.

16. The luminous keyboard according to claim 1, wherein said light guide plate is made of polyethylene terephthalate (PET), polycarbonate (PC), thermoplastic polyurethane (TPU) or polymethylmethacrylate (PMMA).

17. The luminous keyboard according to claim 1, wherein said sensing circuit pattern is formed on a top surface of said reflective plate, or said sensing circuit pattern is formed on a bottom surface of said reflective plate.
